(19) United States
(12) Patent Application Publication
(10) Pub. No.: US 2009/0243055 A1
(43) Pub. Date: Oct. 1, 2009

(54) Leadframe, semiconductor packaging structure and manufacturing method thereof

(76) Inventor: Chin-Ti Chen, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/081,620

(22) Filed: Apr. 18, 2008

(30) Foreign Application Priority Data
Mar. 28, 2008 (TW) 97111472

(51) Int. Cl. H01L 23/495; H05K 7/18; H01L 21/60; H01R 43/00

(52) U.S. Cl. 257/666; 361/813; 438/109; 29/827; 257/E23.031; 257/E21.51

(57) ABSTRACT

A semiconductor packaging structure includes a plurality of first inner leads, a plurality of second inner leads, a plurality of first outer leads, a plurality of stacked chips, an encapsulating body, and a plurality of wires. Wherein, a first protrusion portion is protruded from each of the first inner leads and is formed a plurality of contact faces with height differences, a second protrusion portion is protruded from each of the second inner leads. Therefore, the wires connected to the stacked chips, the first protrusion portion of the first inner leads, and the second protrusion portion of the second inner leads can be shorten. And, the wire sweep and short-circuit can be prevented during molding process. In addition, the present invention also discloses a leadframe and manufacturing method for the leadframe and its semiconductor packaging structure.

### BACKGROUND OF THE INVENTION

1. Field of the Invention

The present invention relates to a leadframe and semiconductor packaging structure and the manufacturing method thereof, and more particularly, to a leadframe and semiconductor packaging structure with a protrusion portion and the manufacturing method thereof.

2. Description of the Prior Art

Along with the rapid progress of the semiconductor technology process and the continuous increase of the packaging density of the Integrated Circuit (IC), the packaging leads of the packaging elements are more and more. Therefore, to manufacture the packaging structures with small volume, rapid speed and high density has been an unavoidable trend. For example, the packaging range of the Thin Small Outline Package (TSOP) and the Lead-On-Chip (LOC) is getting smaller to make the packaging process harder and so that the packaging yield is very difficult to promote.

FIG. 1 is a schematic diagram of a conventional semiconductor packaging structure, which includes: several stacked chips 10a, 10b and 10c; a leadframe 12; wires 14a, 14b, 14c and 14d; and an encapsulating body 16. The leadframe 12 has a plurality of first inner leads 12a, a plurality of second inner leads 12b and a plurality of first outer leads 12c, wherein the first inner leads 12a are set on the central region of the leadframe 12 to accommodate stacked chips 10a, 10b and 10c. However, when the wires 14a, 14b, 14c and 14d of this kind of conventional semiconductor packaging structure connect the stacked chips 10a, 10b and 10c to the first inner leads 12a or the second inner leads 12b, the length of the wires 14a, 14b, 14c and 14d needs to be lengthened if the stacked chips 10a, 10b and 10c gets more. Therefore, the semiconductor packaging structure is easy to sweep wires or fall off during the molding process, and such as to induce a short circuit phenomenon.

Accordingly, this invention provides a leadframe and semiconductor packaging structure and the manufacturing method thereof to effectively solve the aforementioned problems of the prior art.

### SUMMARY OF THE INVENTION

In order to solve the aforementioned problem, one object of the present invention is to provide a leadframe, a semiconductor packaging structure and the manufacturing method thereof, wherein protrusion portions are formed on the inner leads to shorten the wire lengths of the stacked chips.

Another object of the present invention is to provide leadframe, a semiconductor packaging structure and the manufacturing method thereof, wherein the semiconductor packaging structure can resist the pressure caused by the flow of the encapsulating body during the molding process, and such as to prevent the wire sweeping.

Another object of the present invention is to provide leadframe, a semiconductor packaging structure and the manufacturing method thereof, wherein the semiconductor packaging structure can reduce the short circuit phenomenon to effectively promote the production yield.

To achieve the objects mentioned above, one embodiment of the present invention is to provide a leadframe, which includes: a plurality of first inner leads; a plurality of second inner leads; and a plurality of first outer leads; wherein a first protrusion portion is protruded from each of the first inner lead and is formed a plurality of contact faces with height differences, and a second protrusion portion is protruded from each second inner lead.

To achieve the objects mentioned above, one embodiment of the present invention is to provide a semiconductor packaging structure, which includes: a leadframe having a plurality of first inner leads, a plurality of second inner leads and a plurality of first outer leads, wherein each of the first inner lead and each of the second inner lead includes: a first protrusion portion protruded from each of the first inner lead and formed a plurality of contact faces with height differences; and a second protrusion portion protruded from each of the second inner lead; and a plurality of stacked chips set on the first inner lead and adjacent to one side of the first protrusion portion; a plurality of wires electrically connecting the stacked chips to the corresponding contact faces of the first protrusion portion or the second protrusion portion with similar heights correspondingly; and an encapsulating body sealing the stacked chips, the first inner lead, the second inner lead, the first protrusion portion, the second protrusion portion and the wires.

To achieve the objects mentioned above, one embodiment of the present invention is to provide a semiconductor packaging method, which includes: providing a leadframe, wherein the leadframe has a plurality of first inner leads, a plurality of second inner leads and a plurality of first outer leads, wherein a first protrusion portion and a second protrusion portion are separately formed on each of the first inner leads and each of the second inner leads and a plurality of contact faces with height differences are formed on the first protrusion portion; setting a plurality of stacked chips on the first inner leads and adjacent to one side of the first protrusion portion; electrically connecting the stacked chips to the contact faces of the first protrusion portion or the second protrusion portion with similar heights by using a plurality of wires; and sealing the stacked chips, the first inner leads, the second inner leads, the first protrusion portion, the second protrusion portion and the wires.

To achieve the objects mentioned above, one embodiment of the present invention is to provide a leadframe manufacturing method, which includes: processing and forming a leadframe, wherein the leadframe has a plurality of first inner leads, a plurality of second inner leads and a plurality of first outer leads, wherein a first protrusion portion and a second protrusion portion are separately formed on each of the first inner leads and each of the second inner leads, and a plurality of contact faces with height differences are formed on the first protrusion portion.

### BRIEF DESCRIPTION OF THE DRAWINGS

The foregoing aspects and many of the accompanying advantages of this invention will become more readily appreciated as the same becomes better understood by reference to the following detailed description when taken in conjunction with the accompanying drawings, wherein:

FIG. 1 is a schematic diagram of a conventional semiconductor packaging structure;

FIG. 2a and FIG. 2b are the top-view and side-view schematic diagrams of a semiconductor packaging structure separately according to one embodiment of the present invention;

FIG. 3 is the schematic diagram of a semiconductor packaging structure according to another embodiment of the present invention; and

FIG. 4a, FIG. 4b and FIG. 4c are the schematic diagrams of the manufacturing method according to the semiconductor packaging structure of the present invention.

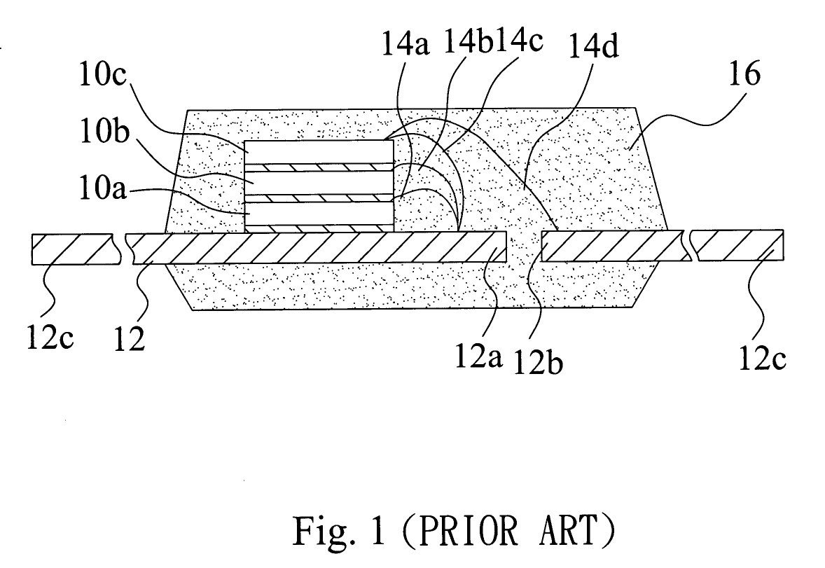

### DESCRIPTION OF THE PREFERRED EMBODIMENT

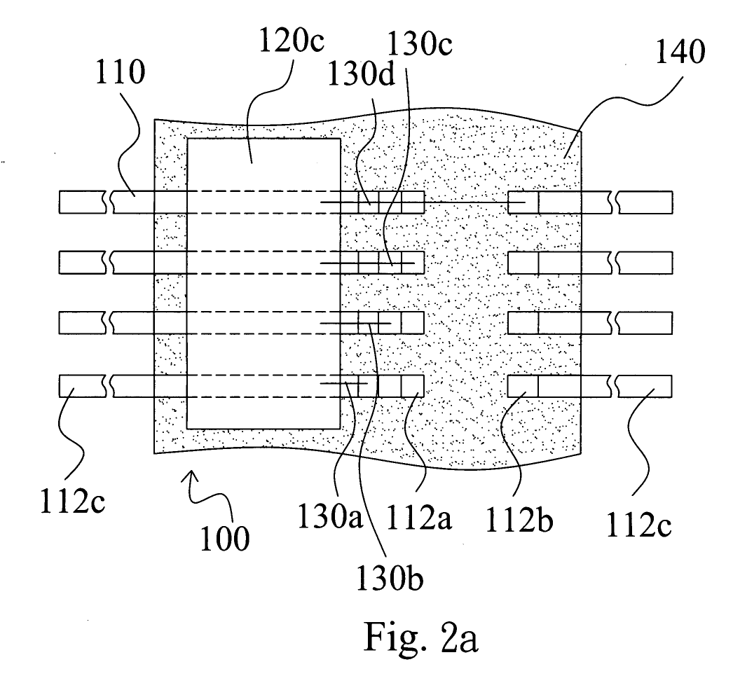

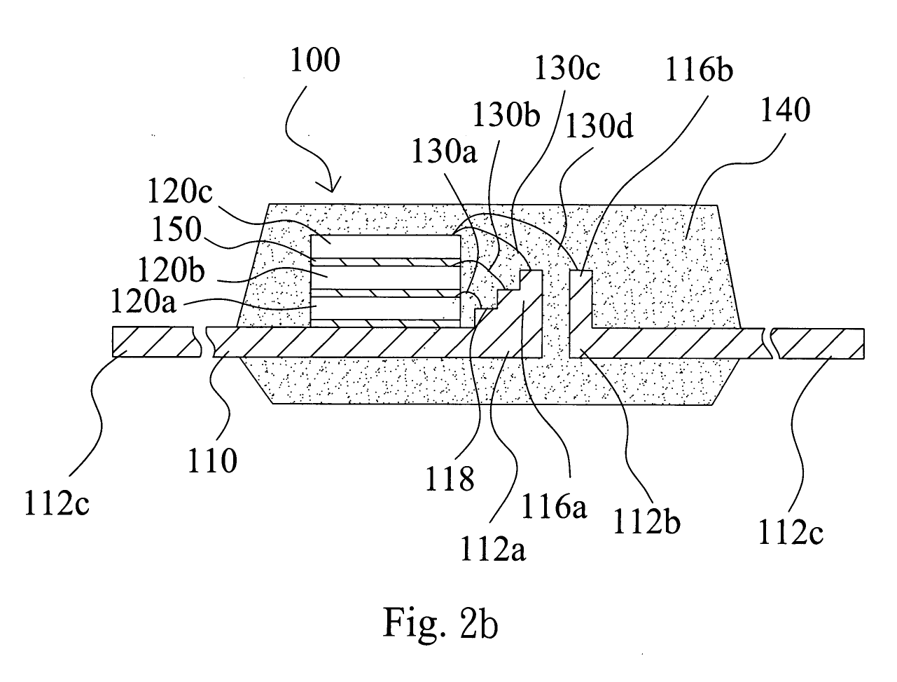

FIG. 2a and FIG. 2b are the top-view and side-view schematic diagrams of a semiconductor packaging structure separately according to one embodiment of the present invention. In this embodiment, semiconductor packaging structure 100 includes: a leadframe 110; a plurality of stacked chips 120a, 120b and 120c; a plurality of wires 130a, 130b, 130c and 130d; and an encapsulating body 140. Wherein the leadframe 110 has a plurality of first inner leads 112a, a plurality of second inner leads 112b and a plurality of first outer leads 112c. A first protrusion portion 116a is protruded from each first inner lead 112a and is formed a plurality of contact faces 118 with height differences, and a second protrusion portion 116b is protruded from each second inner lead 112b. The stacked chips 120a, 120b and 120c are set on the first inner lead 112a and adjacent to one side of the first protrusion portion 116a. The wires 130a, 130b, 130c and 130d electrically connect the stacked chips 120a, 120b and 120c to the corresponding contact faces 118 of the first protrusion portion 116a or the second protrusion portion 116b with similar heights. And, the encapsulating body 140 seals the stacked chips 120a, 120b and 120c, the first inner lead 112a, the second inner lead 112b, the first protrusion portion 116a, the second protrusion portion 116b and the wires 130a, 130b, 130c and 130d. Further, an adhesive 150 is adhered between the stacked chips 120a, 120b and 120c to fix the stacked chips 120a, 120b and 120c.

According to the above description, it is easy to understand that the first protrusion portions of the first inner lead may increase in accordance with the increased height if the stacked chips get more. Therefore, the length of the wires can be shortened, and the shorter length can resist the pressure caused by the flow of the encapsulating body during the molding process, and such as to prevent the sweeping or falling off of the wires. Consequently, the short circuit phenomenon of the semiconductor packaging structure can be reduced to promote the production yield.

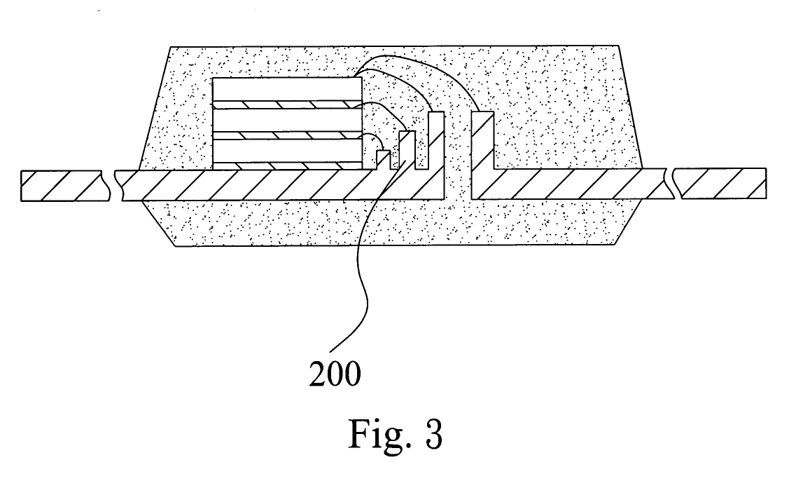

In another preferred embodiment, the first protrusion portion 116a may have a ladder shape as shown in FIG. 2b. Alternatively, the first protrusion portion 200 may have an erect shape as shown in FIG. 3. In other words, all the different structures of the protrusion portion protruded from the inner leads to shorten the length of the connection wires are included in the claimed scope of the present invention, and it is not to further describe hereafter.

In one preferred embodiment, the height of each stacked chip is separately aligned to each contact face of the first protrusion portion to make the wires to connect the first protrusion portion of the first inner lead or the second protrusion portion of the second inner lead with a shortest length. Additionally, in another preferred embodiment, the horizontal heights of the first protrusion portion of the first inner lead and the second protrusion portion of the second inner lead are the same, so that the wire can connect the first protrusion portion of the first inner lead and the second protrusion portion of the second inner lead with a shortest length.

In one preferred embodiment, the quantity of the contact faces and the stacked chips are the same, such that the package height of the semiconductor packaging structure can be controlled to be lowest. In the aforementioned embodiment, the leadframe has a structure of a one-piece form, and the manufacturing method of the leadframe is selected from wet etching, dry etching, casting, stamping or shaping to form the first protrusion portion and the second protrusion portion.

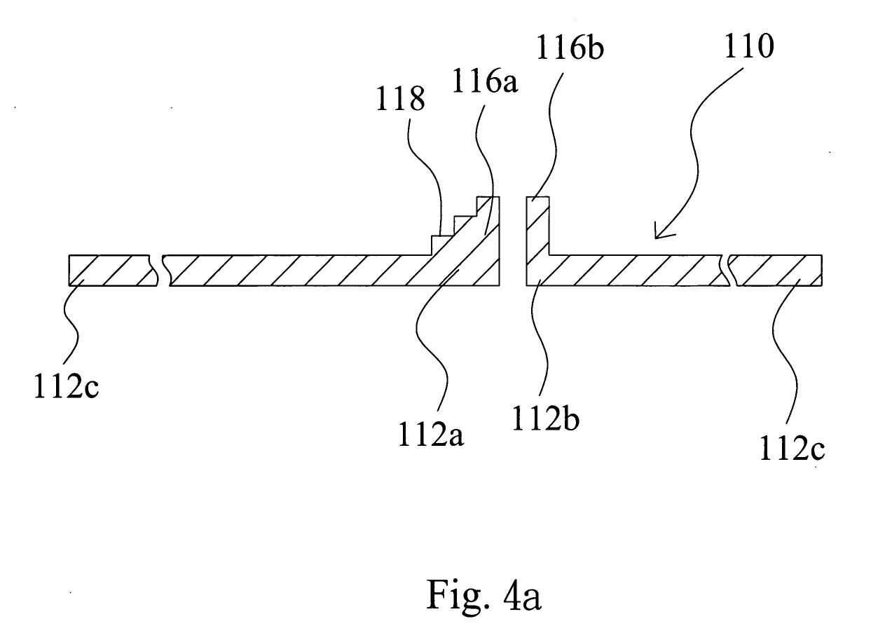

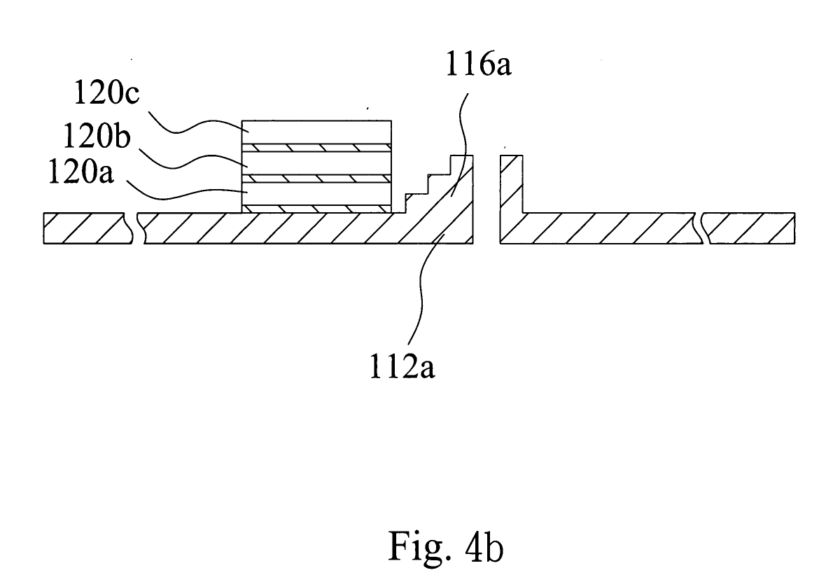

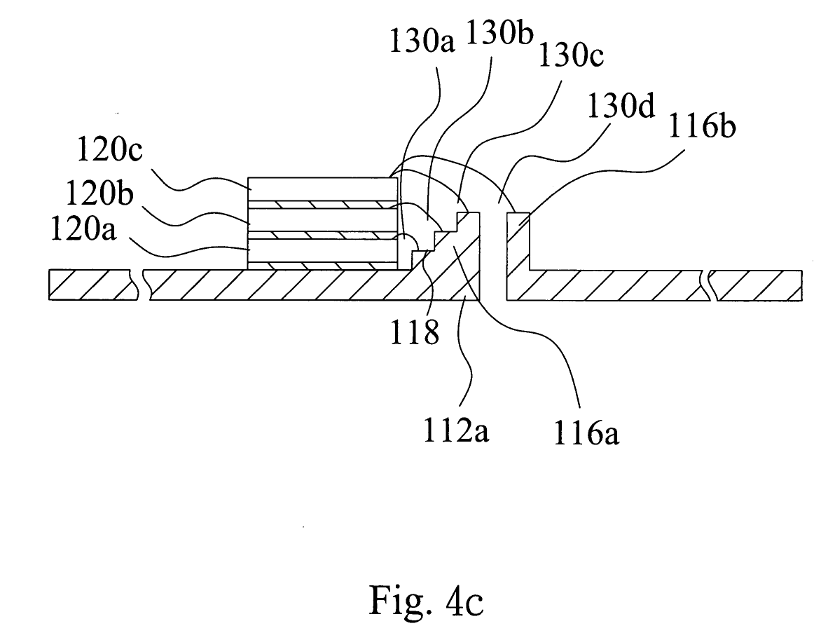

FIG. 4a, FIG. 4b and FIG. 4c are the schematic diagrams of the manufacturing method according to the semiconductor packaging structure of the present invention. First step, as shown in FIG. 4a, is processing and forming a leadframe 110, which has a plurality of first inner leads 112a, a plurality of second inner leads 112b and a plurality of first outer leads 112c. A first protrusion portion 116a and a second protrusion portion 116b are separately formed on the first inner leads 112a and the second inner leads 112b, and a plurality of contact faces 118 with height differences are formed on the first protrusion portion 116a. Next step, as shown in FIG. 4b, is setting a plurality of stacked chips 120a, 120b and 120c on the first inner leads 112a and adjacent to one side of the first protrusion portion 116a. Next step, as shown in FIG. 4c, is electrically connecting the stacked chips 120a, 120b and 120c to the corresponding contact faces 118 of the first protrusion portion 116a and/or the second protrusion portion 116b with similar heights by using a plurality of wires 130a, 130b, 130c and 130d. Final step, please refer to FIG. 2b again, is providing an encapsulating body 140 to seal the stacked chips 120a, 120b and 120c, the first inner lead 112a, the second inner lead 112b, the first protrusion portion 116a, the second protrusion portion 116b and the wires 130a, 130b, 130c and 130d.

In the above embodiment, the leadframe has a structure of the one-piece form, and the manufacturing method of the leadframe is selected from wet etching, dry etching, casting, stamping or shaping to form the first protrusion portion and the second protrusion portion.

Further, an adhering step may adhere an adhesive between the stacked chips, and the adhesive may be a tape or a DAF adhesive.

To sum up, the present invention provides a leadframe, a semiconductor packaging structure and the manufacturing method thereof. The protrusion portions formed on the inner leads may shorten the lengths of the wires. Furthermore, the wire sweeping and the short circuit phenomenons of the semiconductor packaging structure can be reduced during the molding process to effectively promote the production yield.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. A semiconductor packaging structure, comprising:
a leadframe having a plurality of first inner leads, a plurality of second inner leads and a plurality of first outer leads, wherein each of the first inner lead and each of the second inner lead comprising:
a first protrusion portion protruded from each of the first inner lead and formed a plurality of contact faces with height differences; and
a second protrusion portion protruded from each of the second inner lead;
a plurality of stacked chips set on the first inner lead and adjacent to one side of the first protrusion portion;
a plurality of wires electrically connecting the stacked chips to the corresponding contact faces of the first protrusion portion or the second protrusion portion with similar heights; and
an encapsulating body sealing the stacked chips, the first inner lead, the second inner lead, the first protrusion portion, the second protrusion portion and the wires.

2. The semiconductor packaging structure according to claim 1, wherein the first protrusion portion has a ladder shape or an erect shape.

3. The semiconductor packaging structure according to claim 1, wherein the height of each stacked chip is separately aligned to each contact face of the first protrusion portion.

4. The semiconductor packaging structure according to claim 1, wherein horizontal heights of the first protrusion portion and the second protrusion portion are the same.

5. The semiconductor packaging structure according to claim 1, wherein the leadframe has a structure of a one-piece form.

6. The semiconductor packaging structure according to claim 1, wherein the quantity of the contact faces and the stacked chips are the same.

7. A leadframe, comprising:
a plurality of first inner leads;
a first protrusion portion protruded from each of the first inner lead and formed a plurality of contact faces with height differences;
a plurality of second inner leads;
a second protrusion portion protruded from each of the second inner lead; and
a plurality of first outer leads.

8. The leadframe according to claim 7, wherein the first protrusion portion has a ladder shape or an erect shape.

9. The leadframe according to claim 7, wherein horizontal heights of the first protrusion portion and the second protrusion portion are the same.

10. The leadframe according to claim 7, wherein the leadframe has a structure of a one-piece form.

11. The leadframe according to claim 7, wherein the first protrusion portion and the second protrusion portion are formed by wet etching, dry etching, casting, stamping or shaping.

12. A semiconductor packaging method, comprising:
providing a leadframe, wherein the leadframe has a plurality of first inner leads, a plurality of second inner leads and a plurality of first outer leads; wherein a first protrusion portion and a second protrusion portion are separately formed on each of the first inner leads and each of the second inner leads; and a plurality of contact faces with height differences are formed on the first protrusion portion;
setting a plurality of stacked chips on the first inner leads and adjacent to one side of the first protrusion portion;
electrically connecting the stacked chips to the contact faces of the first protrusion portion or the second protrusion portion with similar heights by using a plurality of wires; and
sealing the stacked chips, the first inner lead, the second inner lead, the first protrusion portion, the second protrusion portion and the wires.

13. The semiconductor packaging method according to claim 12, wherein the first protrusion portion and the second protrusion portion are formed by wet etching, dry etching, casting, stamping or shaping.

14. The semiconductor packaging method according to claim 12, wherein the height of each stacked chip is separately aligned to each of the contact faces of the first protrusion portion.

15. The semiconductor packaging method according to claim 12, wherein horizontal heights of the first protrusion portion and the second protrusion portion are the same.

16. The semiconductor packaging method according to claim 12, further comprising an adhering step to adhere an adhesive between the stacked chips.

17. A leadframe manufacturing method, comprising:
processing and forming a leadframe, wherein the leadframe has a plurality of first inner leads, a plurality of second inner leads and a plurality of first outer leads, wherein a first protrusion portion and a second protrusion portion are separately formed on each of the first inner leads and each of the second inner leads, and a plurality of contact faces with height differences are formed on the first protrusion portion.

18. The leadframe manufacturing method according to claim 17, wherein the first protrusion portion and the second protrusion portion are formed by wet etching, dry etching, casting, stamping or shaping.

19. The leadframe manufacturing method according to claim 17, wherein horizontal heights of the first protrusion portion and the second protrusion portion are the same.
